(19) United States
(12) Patent Application Publication
(10) Pub. No.: US 2019/0222012 A1
(43) Pub. Date: Jul. 18, 2019

(54) CABLE OR WIRE ORGANIZATION SYSTEM

(71) Applicant: Jorge Lopez, The Colony, TX (US)

(72) Inventor: Jorge Lopez, The Colony, TX (US)

(21) Appl. No.: 16/246,484

(22) Filed: Jan. 12, 2019

Related U.S. Application Data
(60) Provisional application No. 62/616,602, filed on Jan. 12, 2018.

(51) Int. Cl. H02G 3/30; H05K 5/02; H02G 3/02

(52) U.S. Cl. CPC H02G 3/30; H02G 3/02; H05K 5/0247; H05K 5/0226

(57) ABSTRACT

A cable or wire organization system enables the ordering of multiple strands into a bundle while maintaining the identity of each. The system reduces the chance of losing or letting a cable slip from where it is known. The system opens in a clamshell style to allow the cables to be placed in retainers before the system is closed to secure the cables. The system is once piece so to facilitate the system remaining in take after multiple uses.

### BACKGROUND

### 1. Field of the Invention

The present invention relates generally to cables and wires, and more specifically, to tools that facilitate placement, organization or sorting of multiple cables, wires or strands in a group.

### 2. Description of Related Art

Cables and wires are common means of connecting two objects. They are found in construction, machines, communications and so on. Communication networks are one common use and includes computing devices linked by signals commonly transmitted over cables. These cables are bundled together for simplicity and efficiency in locating a particular cable in the bundle. For example, FIG. 1 depicts a conventional cable sorting device 101 having an inside core 103 with slots 105 configured to hold cables around the perimeter 107 and a securing band 109 to retain the cables in the slots 105. The cables are then pulled through the core to sort them. The device 101 can be rotated to twist the cables in to a bundle.

One of the problems commonly associated with device 101 is its limited efficiency. For example, when placing or removing the cables from the core 103 they can slip or fall out resulting in a loss of identification for which slot it came from.

Accordingly, although great strides have been made in the area of cable sorting devices 101, many shortcomings remain.

### DESCRIPTION OF THE DRAWINGS

The novel features believed characteristic of the embodiments of the present application are set forth in the appended claims. However, the embodiments themselves, as well as a preferred mode of use, and further objectives and advantages thereof, will best be understood by reference to the following detailed description when read in conjunction with the accompanying drawings, wherein:

FIG. 1 is a front view of a common cable sorting device;

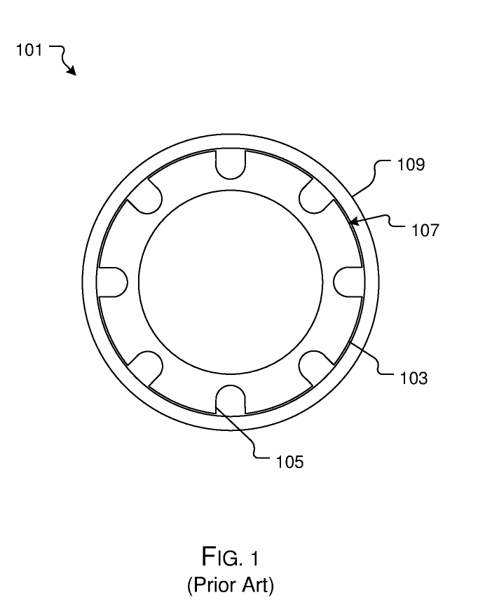

FIGS. 2A and 2B are front views of a cable or wire organization system in accordance with a preferred embodiment of the present application;

FIG. 3 is a top view of the retainer of FIGS. 2A and 2B;

FIG. 4 is a perspective view of an alternative embodiment of the system of FIGS. 2A and 2B;

FIGS. 5A and 5B are front views of an alternative embodiment of the system of FIGS. 2A and 2B; and

FIG. 6 is a side view of an alternative embodiment of the system of FIGS. 2A and 2B.

While the system and method of use of the present application is susceptible to various modifications and alternative forms, specific embodiments thereof have been shown by way of example in the drawings and are herein described in detail. It should be understood, however, that the description herein of specific embodiments is not intended to limit the invention to the particular embodiment disclosed, but on the contrary, the intention is to cover all modifications, equivalents, and alternatives falling within the spirit and scope of the present application as defined by the appended claims.

### DETAILED DESCRIPTION OF THE PREFERRED EMBODIMENT

Illustrative embodiments of the system and method of use of the present application are provided below. It will of course be appreciated that in the development of any actual embodiment, numerous implementation-specific decisions will be made to achieve the developer's specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The system and method of use in accordance with the present application overcomes one or more of the above-discussed problems commonly associated with conventional cable sorting devices. Specifically, the system of the present application reduces the change of a cable or cables falling from the tool so that the identity of the cables are maintained. These and other unique features of the system and method of use are discussed below and illustrated in the accompanying drawings.

The system and method of use will be understood, both as to its structure and operation, from the accompanying drawings, taken in conjunction with the accompanying description. Several embodiments of the system are presented herein. It should be understood that various components, parts, and features of the different embodiments may be combined together and/or interchanged with one another, all of which are within the scope of the present application, even though not all variations and particular embodiments are shown in the drawings. It should also be understood that the mixing and matching of features, elements, and/or functions between various embodiments is expressly contemplated herein so that one of ordinary skill in the art would appreciate from this disclosure that the features, elements, and/or functions of one embodiment may be incorporated into another embodiment as appropriate, unless described otherwise.

The preferred embodiment herein described is not intended to be exhaustive or to limit the invention to the precise form disclosed. It is chosen and described to explain the principles of the invention and its application and practical use to enable others skilled in the art to follow its teachings.

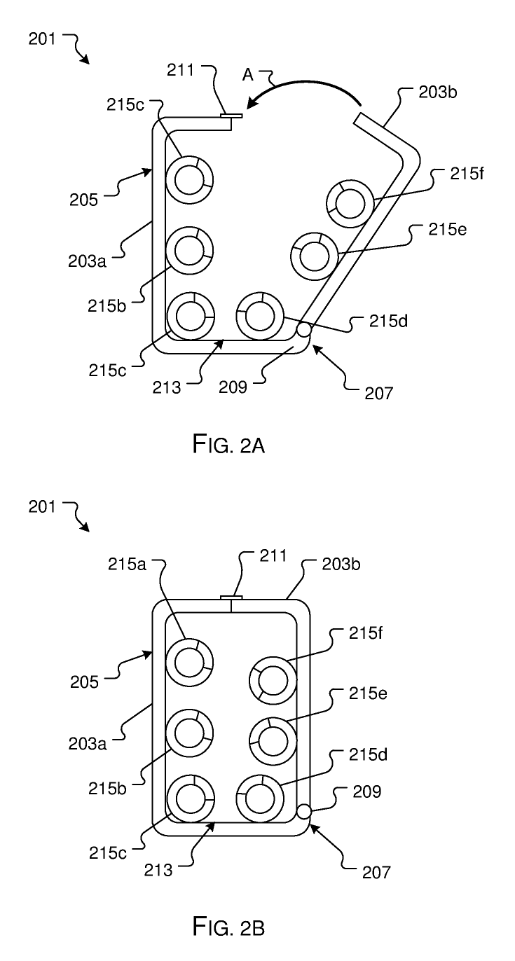

Referring now to the drawings wherein like reference characters identify corresponding or similar elements throughout the several views, FIGS. 2A and 2B depicts front views of a cable or wire organization system in accordance with a preferred embodiment of the present application. It will be appreciated that system 201 overcomes one or more of the above-listed problems commonly associated with conventional cable sorting devices.

In the contemplated embodiment, system 201 includes body 203 that is open at a first end 205 and a second end 207. The second end 207 being joined by a hinge 209. The first end 205 being closable via a fastener 211. The interior surface 213 of the body 203 having retainers 215 attached thereto.

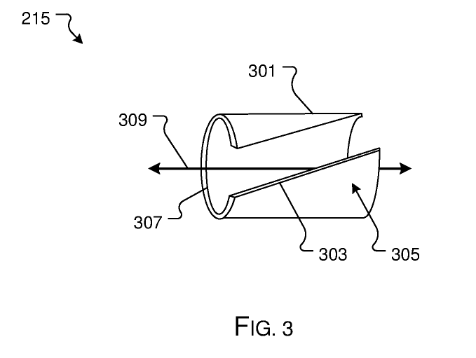

The retainers 215 having a generally cylindrical member 301 as depicted in FIG. 3. The member 301 having an opening 303 that passes through the outer surface 305 to a hollow center 307. The opening 303 being non parallel to the member's long axis 309. The cables remain in the retainer 215 via the shape of the opening and the natural tendency of the cables to remain generally strait. It will be understood that once in the retainer 215 the cable will generally align its self with the long axis 309 of the member 301.

In use, cables are placed in the retainers 215 by aligning the cable with the opening 303. The system 201, when loaded with cables, is closed as depicted by motion A and secured via the fastener 211. The system is pulled or rotated to create an orderly bundle of cables.

It should be appreciated that one of the unique features believed characteristic of the present application is that retainers 215 prevent the loss of the cables so that the identity of each is maintained. It will also be appreciated that the system is self-contained so that there are no removable parts or pieces increases the ability of a user to retain they system in a working condition. It will be understood that many devices common in the art are of multiple parts and that loss of one part renders the entire device unusable and if still usable, only by difficulty and extreme effort.

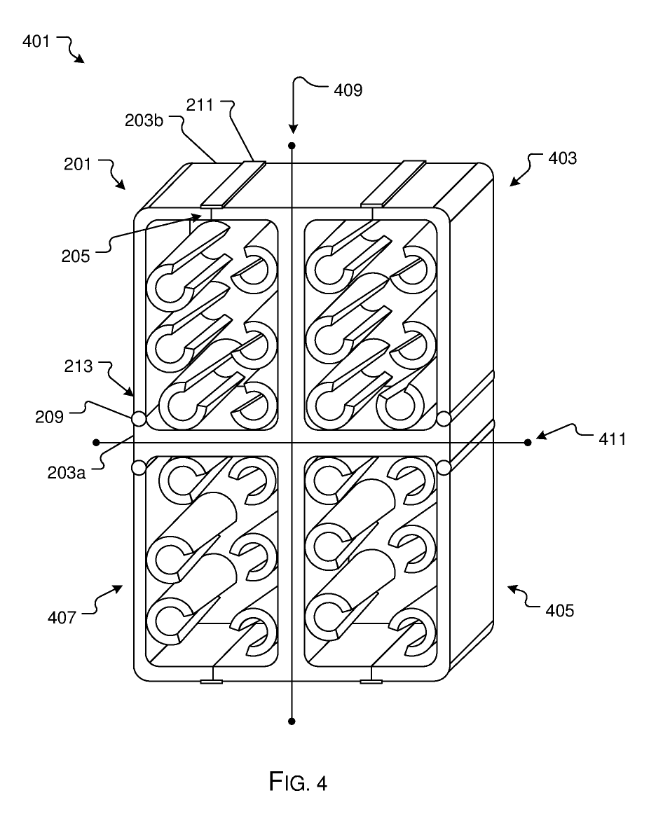

Referring now to FIG. 4 an alternative embodiment of the system 201 is depicted. Embodiment 401 including a first cable or wire organization system 201 fixedly attached to a second cable or wire organization system 403, a third cable or wire organization system 405 and a fourth cable or wire organization system 407. A portion of the first body 203 being adhered to the opposite area of the second system 403 and fourth system 407 along axis 409 and 411 respectively. The third system 405 being attached the second system 403 and fourth system 407 along axis 411 and 409 respectively.

In this fashion both systems 201, 403, 405 and 407 open to allow cables to be placed in the retainers 215 while expanding the total number cables to be organized. While four systems have been depicted any number or configuration is anticipated or contemplated.

Another unique feature believed characteristic of the present application is that any number of cable or wire organization systems 201 can be grouped together to alter the capacity as needed. While it has been depicted that the first system 201 is adhered to a second system 403 fasteners or any method of joining the two is considered.

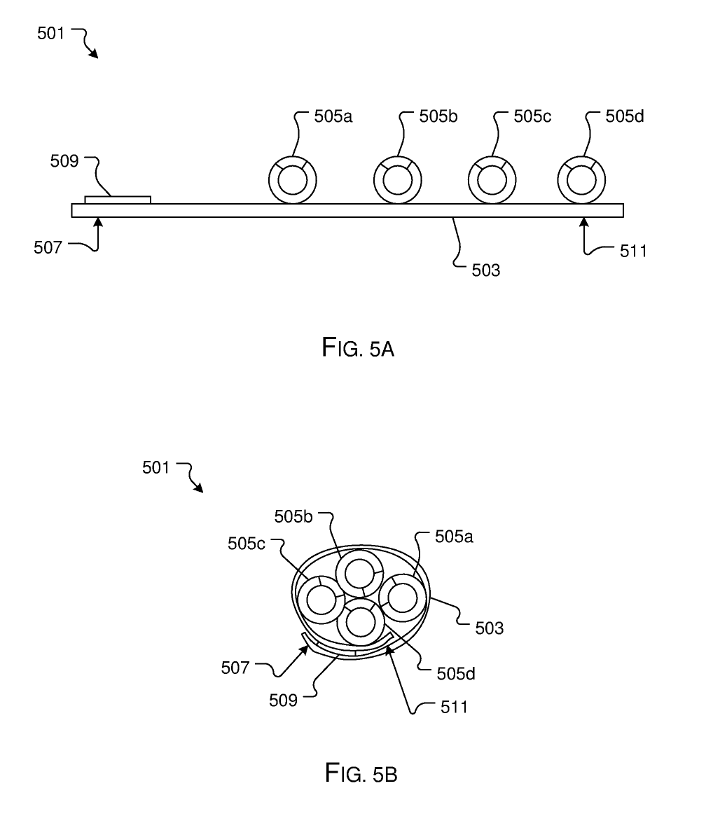

Referring now to FIGS. 5A and 5B an alternative embodiment of system 201 is depicted. Embodiment 501 including a pliable band 503 having retainers 505 attached thereto. A first end 507 having a fastener 509 attached.

In use, cables are placed in the retainers and the band 503 is rolled up from a second end 511. The first end 509 attached to the band 503 to secure the roll. It will be appreciated that in this manner they system 501 is able to group and organize multiple cables while efficiently preserving the identity of each.

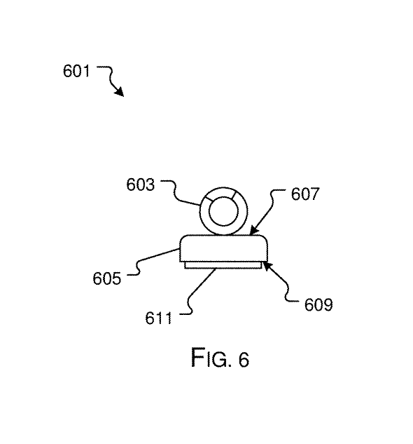

Referring now to FIG. 6 an alternative embodiment of system 201 is depicted. Embodiment 601 including a retainer 603 attached to the top surface 607 of a base 605. The base 605 having an adhesive layer 611 attached to the bottom surface 609.

It will be appreciated that in this manner a single cable can be efficiently organized and attached to so other structure or surface.

The particular embodiments disclosed above are illustrative only, as the embodiments may be modified and practiced in different but equivalent manners apparent to those skilled in the art having the benefit of the teachings herein. It is therefore evident that the particular embodiments disclosed above may be altered or modified, and all such variations are considered within the scope and spirit of the application. Accordingly, the protection sought herein is as set forth in the description. Although the present embodiments are shown above, they are not limited to just these embodiments, but are amenable to various changes and modifications without departing from the spirit thereof.

What is claimed:

1. A cable or wire organization system comprising:
a body having an opening at a first end and a second end having a fastener at the first end and hinge at the second end so that the two halves open and close; and
a plurality of retainers attached to the interior surface of the body;
wherein cables are held in the retainers while a plurality of cables are bundled together.

2. A cable or wire organization system comprising:
a first body having an opening at a first end and a second end having a fastener at the first end and hinge at the second end so that the two halves open and close;
a plurality of retainers attached to the interior surface of the body;
at least one other body having an opening at a first end and a second end having a fastener at the first end and hinge at the second end so that the two halves open and close; and
a plurality of retainers attached to the interior surface of the body;
wherein the first and other bodies are joined together for a continuous system;
wherein cables are held in the retainers while a plurality of cables are bundled together.

3. A cable or wire organization system comprising:
a pliable body having a fastener attached a second end; and
a plurality of retainers attached to the body beginning at the second end.
wherein cables are placed in the retainers;
wherein the pliable body it rolled up from the second end; and
wherein the cables are bundled together.

4. A cable or wire organization system comprising a base having at least one retainer attached to the top surface and an adhesive layer attached to the bottom surface; wherein cables are held in the retainer and secured to another object.

5. A retainer comprising:
a generally cylindrical member having an opening passing through the outer surface to a hollow center;
the opening being non parallel to the member's long axis;
wherein a cable is placed in therein via aligning the cable with the opening and passing there through.
